(19) United States
(12) Patent Application Publication
(10) Pub. No.: US 2014/0090686 A1
(43) Pub. Date: Apr. 3, 2014

(54) METHODS AND APPARATUS FOR CONCENTRATING PHOTOVOLTAICS

(71) Applicant: The Massachusetts Institute of Technology, (US)

(72) Inventors: Anuradha M. Agarwal, Weston, MA (US); Brian R. Albert, Cambridge, MA (US); Lirong Zeng Broderick, Cambridge, MA (US); Jing Cheng, Malden, MA (US); Juejun Hu, Newark, DE (US); Lionel Kimerling, Concord, MA (US); Jifeng Liu, Hanover, NH (US); Jurgen Michel, Arlington, MA (US); Xing Sheng, Cambridge, MA (US)

(73) Assignee: The Massachusetts Institute of Technology, Cambridge, MA (US)

(21) Appl. No.: 13/651,140

(22) Filed: Oct. 12, 2012

Related U.S. Application Data
(60) Provisional application No. 61/547,431, filed on Oct. 14, 2011.

(51) Int. Cl. H01L 31/052

(52) U.S. Cl. CPC H01L 31/0528
USPC 136/246; 136/244; 438/80

(57) ABSTRACT

Provided in one embodiment is an article, comprising: a substrate comprising silicon; and a plurality of solar cells disposed over the substrate, wherein at least one of the plurality of the solar cells comprises one of: (i) a first semiconductor layer disposed over the substrate, the first layer comprising at least one semiconductor material; and (ii) a first Ge-containing layer disposed over the substrate, the first layer comprising a Ge-containing material, and a second layer disposed over the first layer, the second layer comprising at least one semiconductor material. At least some of the solar cells may comprise semiconductor materials of different bandgap values.

### RELATED APPLICATION

This application claims priority from U.S. Provisional Application Ser. No. 61/547,431, filed Oct. 14, 2011, which is hereby incorporated by reference in its entirety.

### BACKGROUND

While concentrating photovoltaic technology is a promising method to increase solar cell efficiencies, the cost of the system may be reduced by using less semiconductor materials through inexpensive concentrating optics. Traditional solar cells used in concentrating systems face several challenges. For example, they may include vertically stacked III-V multijunctions, which use expensive III-V or Ge substrates; they generally may involve complicated film growth techniques for lattice matching and forming tunnel junctions; and they may demand current matching that is difficult to optimize for varying weather conditions (and thus limit the efficiencies of the solar cells.)

An improvement to direct vertical stacking is splitting the solar spectrum into several bands directed towards discrete solar cells with spectrally matched bandgaps. This eliminates the need for current matching and allows the cells to be optimized independently to minimize the need for lattice matching, thereby enabling freedom in choosing materials based on considerations of bandgaps. However, each of the discrete solar cells may need an expensive substrate, such as GaAs, InP, or Ge for III-V junctions or a Ge cell itself. Furthermore, mounting may be difficult and costly, and the relatively large distances between adjacent solar cells (limited by physical mounting) may waste some parts of the solar spectrum, thereby reducing efficiency.

### SUMMARY

In view of the foregoing, the present Inventors have recognized and appreciated the advantages of a system including a plurality of solar cells implemented on a common substrate and configured to reduce optical loss related to spectrum splitting.

Accordingly, provided in one embodiment is an article, comprising: a substrate comprising silicon; and a plurality of solar cells disposed over the substrate, wherein at least one of the plurality of the solar cells comprises one of: (i) a first semiconductor layer disposed over the substrate, the first layer comprising at least one semiconductor material; and (ii) a first Ge-containing layer disposed over the substrate, the first layer comprising a Ge-containing material, and a second layer disposed over the first layer, the second layer comprising at least one semiconductor material.

Provided in another embodiment is an article, comprising: a substrate comprising silicon; and a plurality of solar cells disposed over the substrate and electrically isolated from one another. At least some of the solar cells may comprise semiconductor materials having different bandgap values.

Provided in another embodiment is method comprising: disposing a plurality of solar cells over a substrate comprising silicon; and isolating electrically at least some of the plurality of solar cells. At least some of the solar cells may comprise semiconductor materials having different bandgap values.

Provided in another embodiment is an article, comprising: a substrate comprising silicon; and a plurality of solar cells disposed over the substrate and electrically isolated from one another, wherein at least one of the plurality of the solar cells may comprise layers of one or more semiconductor materials disposed over the Si substrate. At least one of the plurality of the solar cells may comprise a layer comprising one or more silicon-germanium alloys disposed over the Si substrate and at least one additional layer comprising at least one semiconductor material disposed over the alloy layer. In one embodiment, at least one of the plurality of the solar cells may comprise a layer comprising germanium disposed over the Si substrate and at least one additional layer comprising one or more semiconductor materials disposed over the germanium layer.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIG. 1 shows a schematic of the integrated solar cells adapted for spectrum splitting/concentration in one embodiment.

FIG. 2 shows a cross sectional view of an integrated solar cell in one embodiment.

FIG. 3 illustrates an embodiment of junction isolation using thermal gradient zone melting (TGZM) in one embodiment.

FIG. 4 illustrates an alternative embodiment that employs another junction isolation technique by combining trench etching and vertical junctions in one embodiment.

FIG. 5 illustrates a comparison of efficiencies achievable from parallel junction solar cells integrated on a common Si substrate under one sun and 200× concentration in one embodiment.

FIG. 6 illustrates absorption spectra of integrated three parallel junction InGaP—GaAs—Ge cell and four parallel junction InGaP—GaAs—Si—Ge cell in one embodiment; the solar spectrum is shown on the right axis.

FIG. 7 illustrates a schematic of the cross-section of Si and Ge integrated solar cell where electrical isolation is obtained by trench etching and refilled with SiO₂ in one embodiment.

FIG. 8 illustrates crosstalk current vs. isolation trench width for two different trench depths in one embodiment; the value of the current is for solar cells with unit width (1 cm).

### DETAILED DESCRIPTION

Following below are more detailed descriptions of various concepts related to, and embodiments of, inventive solar spectrum splitting methods and apparatuses for concentrating photovoltaics. It should be appreciated that various concepts introduced above and discussed in greater detail below may be implemented in any of numerous ways, as the disclosed concepts are not limited to any particular manner of implementation. Examples of specific implementations and applications are provided primarily for illustrative purposes.

### Integrated Solar Cell System

Provided in one embodiment is an integrated solar cell system, which employs materials (e.g., semiconductor materials) with different bandgap values to absorb different spectral bands of an incident energy (e.g., solar radiation). As will be described below, based on an Si platform (e.g., commercially available), the high efficiency systems articles described herein may be fabricated through a low-cost and complementary metal-oxide-semiconductor (“CMOS”) compatible process.

One embodiment described herein provides an article, the article comprising: a substrate comprising silicon; and a plurality of solar cells disposed over the substrate and electrically isolated from one another. In one embodiment, at least some of the solar cells comprise semiconductor materials having different bandgap values. The bandgap value of the solar cells may vary, depending on the material employed, and is not limited to any particular value.

In one alternative embodiment, an article described herein may comprise: a substrate comprising silicon; and a plurality of solar cells disposed over the substrate and electrically isolated from one another, wherein at least one of the plurality comprises a first layer comprising silicon; a second layer comprising germanium disposed over the first layer; and a third layer comprising a III-V semiconductor material disposed over the second layer.

The solar cells in the plurality may have the same or different configurations. Also, not all of the solar cells need to be electrically isolated from one another. At least one of the solar cells described herein may comprise multiple layers of one or more materials. In one embodiment, at least one of the plurality of the solar cells may comprise layers of one or more semiconductor materials directly disposed over the Si substrate. And at least one of the plurality of the solar cells may comprise a layer comprising one or more silicon-germanium alloys disposed over the Si substrate; and additional layers comprising one or more semiconductor materials disposed over the silicon-germanium alloy layer. And at least one of the plurality of the solar cells may comprise a layer comprising germanium disposed over the Si substrate; and additional layers comprising one or more semiconductor materials disposed over the germanium layer.

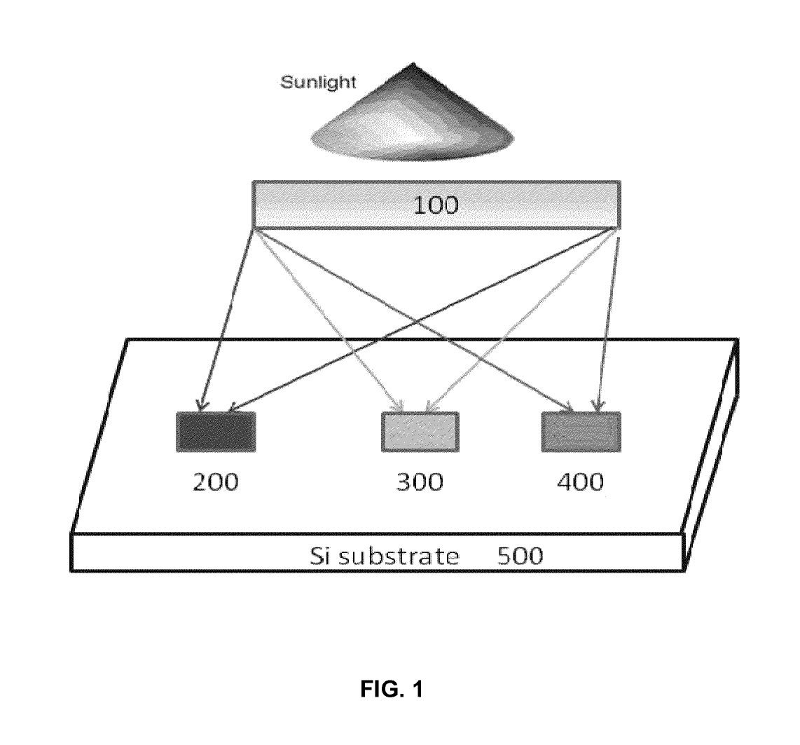

FIG. 1 provides a schematic of an integrated solar cell system in one illustrative embodiment. The system may have an optical element 100, which may split and concentrate incident solar radiation simultaneously or sequentially. A plurality of solar cells 200, 300, and 400 may be present and they may contain materials with different bandgap values (e.g., GaAs, Si, and Ge, respectively, in this embodiment, but they may be in any order). In this embodiment, these solar cells are laterally aligned on the Si substrate 500, although other types of alignments are also possible. The substrate may comprise silicon, or it may consist essentially of silicon. In one embodiment, it consists of silicon. As an example, solar cells containing three materials are shown in this embodiment, but four or more cells, such as five, six, or more, may be possible. Alternatively, two solar cells may also be used.

In one embodiment, multiple solar cells are used. These solar cells may be disposed laterally over a substrate. Alternatively, some may be vertically stacked together. In one embodiment, an InGaP cell may be disposed over a GaAs cell (which may in turn be disposed over a Ge-containing buffer layer). Other types of semiconductor materials may be employed, depending on the application.

The Si of the substrate and the Si of the solar cell disposed over the substrate (“first layer”) may be the same or different from each other. For example, at least one of these two Si may be doped. They may be doped with the same or different type of charge carrier (e.g., n-type or p-type) or they may be doped with the same or different levels of carrier concentration. In one embodiment, the first layer and the substrate contain different types of doped silicon (e.g., one is n-type while the other is p-type.) In an alternative embodiment, the first layer and the substrate comprise the same type of doped silicon.

The Ge-containing layer may comprise a Ge-containing material. The Ge-containing material may be, for example, a Ge-containing semiconductor material. In one embodiment, the Ge-containing material may comprise at least one of Ge and Si₁₋ₓGeₓ alloy. In one embodiment, the Ge-containing or Si₁₋ₓGeₓ alloy layer may be a single crystalline thin film. This film may be an epitaxial film that may be epitaxially grown on a substrate—e.g., a Si layer which acts as a substrate (or is a substrate). The Ge or Si₁₋ₓGeₓ alloy epitaxy film may in turn be employed as a virtual substrate for growing a semiconductor material. In one embodiment, a virtual substrate may be a deposited thin film layer over which to grow a material of a different lattice constant from that of the original substrate.

The semiconductor material may be disposed over a Si-containing substrate directly, or over an intermediate layer, which may comprise a semiconductor material, such as a Ge-containing material, such as any of those described herein. A semiconductor material in at least one embodiment herein may refer to a material comprising at least one of an elemental, an alloy, and a compound semiconductor material. An alloy in at least one embodiment herein may refer to a solid solution or homogeneous mixture of two or more elements. On the other hand, a compound may refer to a substance formed due to the chemical reaction between two or more atoms or molecules—in other words, the elements/molecules are chemically bound in a compound. For example, GaAs, InAs are both semiconductor compounds, whereas GaₓIn(₁₋ₓ)As is an alloy of the compounds GaAs and InAs when x is not 1 or 0. ZnS and ZnSe are both compounds whereas ZnSₓSe(₁₋ₓ) is an alloy of the compounds ZnS and ZnSe when x is not 1 or 0. In one alternative embodiment, the formula ZnSxSe(₁₋ₓ) can refer to an alloy (if x is not 0 or 1), or a compound ZnS (x=1) or ZnSe (x=0).

A semiconductor material may be an element (e.g., Si or Ge), compound (e.g., GaAs), or alloy (e.g., InₓGa(₁₋ₓ)P, which is an alloy of InP and GaP when x is not 1 or 0). The semiconductor material in one embodiment herein may include at least one of a III-V semiconductor material, a II-VI semiconductor material, a I-III-VI₂ semiconductor material, and a II-IV-V₂ semiconductor material. In one embodiment, the semiconductor material comprises at least one III-V semiconductor material selected from AlₓGa_{y}In_{1-x-y}P, AlₓGa_{y}In_{1-x-y}As and AlₓGa₁₋ₓN_{y}P_{1-y}, where 0≦x≦1 and 0≦y≦1. In another embodiment, the semiconductor material comprising a II-VI semiconductor material herein may be at least one II-VI semiconductor material comprising ZnₓCd₁₋ₓS_{y}Se_{z}Te_{1-y-z}, where 0≦x≦1, 0≦y≦1 and 0≦z≦1. In another embodiment, the semiconductor material comprises at least one I-III-VI₂ semiconductor material comprising Cu(AlₓGa_{y}In_{1-x-y})(S_{z}Se_{1-z})₂, where 0≦x≦1, 0≦y≦1, and 0≦z≦1. In another embodiment, the semiconductor material comprises at least one II-IV-V₂ semiconductor material comprising Zn(SiₓGe₁₋ₓ)P₂, where 0≦x≦1. Note that the aforementioned semiconductor materials are only illustrative examples, and other types of semiconductor materials may be employed, depending on the application.

In one embodiment, the semiconductor material herein may include at least one of a homogeneous p-n junction (“homojunction”) and a heterogeneous p-n junction (“heterojunction”). In one embodiment wherein the junction is a heterojunction, solar cells may comprise two different semiconductor materials, one for the p-region, and the other for the n-region—e.g., AlGaAs for n region, and GaAs for the p region. In another embodiment wherein the junction is a homojunction, the n and p regions may comprise the same semiconductor—e.g., GaAs.

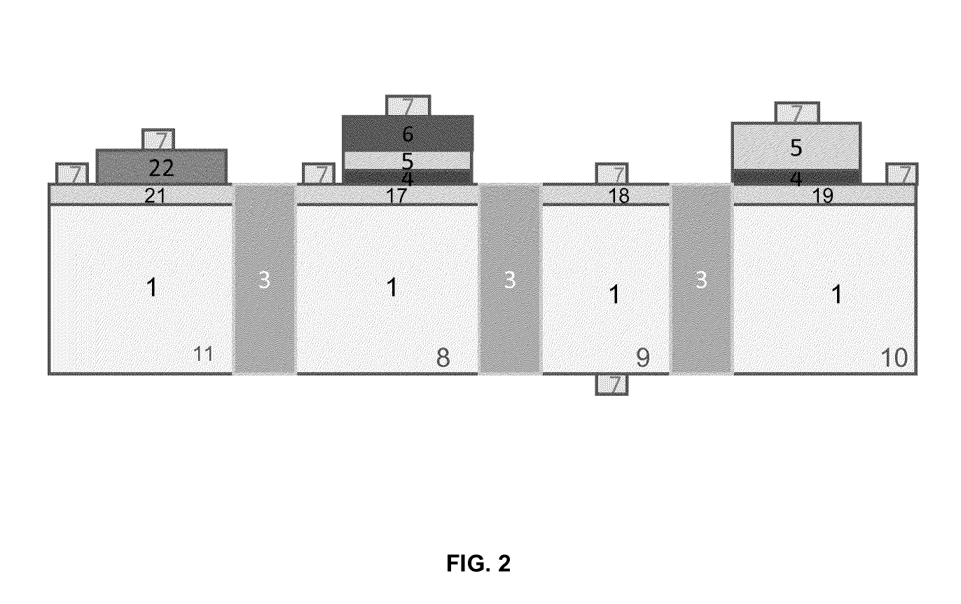

FIG. 2 provides a cross-sectional view of the integrated solar cells shown in FIG. 1. Four cells are disposed over the same Si substrate 1 in regions 8, 9, 10 and 11. They are electrically isolated from one another by element 3 in this embodiment. Electrical isolation is described in a later section. As will be shown below, the isolation may be accomplished by a variety of techniques. Examples include silicon-on-insulator wafers, thermal gradient zone melting, trench etching, vertical junction isolation, or combinations thereof. Each of the solar cells may comprise one layer or multiple layers of material(s). The materials in the layers may be the same or different.

As shown in FIG. 2, an inexpensive Si substrate is employed for different epitaxial growth in this embodiment. In region 11, a semiconductor material lattice-matched to Si (lattice constant a=5.431 A) may be directly grown on the Si substrate epitaxially. Thus, in one embodiment, heavily doped region 21 (as well as regions 17 and 19) may not be necessary if the bottom part of the semiconductor material with a certain doping type is exposed through etching and one of the electrodes 7 contacts the exposed area. In one embodiment, depending on the processing conditions, direct epitaxy on Si substrate may be more efficient than epitaxy through an intermediate Ge-containing layer. In some embodiments, due at least in part to the smaller lattice constant of Si (rather than Ge), the semiconductor materials that may be directly epitaxially grown on Si may tend to have a bigger bandgap energy than the materials that can be epitaxially grown on Ge or Si—Ge alloy buffer layer on Si substrate. As a result, the former may only absorb part of the solar spectrum with short wavelengths. In some embodiments, this difference in absorption may be mitigated by the systems in at least some cases described herein, where systems comprise additional regions with epitaxy through the Ge or Si—Ge alloy buffer layer to include semiconductors with smaller bandgap energies to absorb longer wavelengths of the solar spectrum.

For instance, in region 8 on the same substrate, a semiconductor material may be epitaxially grown on the Ge or Si—Ge alloy buffer layers 4 and 5. Because it is generally desirable to have big bandgap materials (as shown by the simulation results described below), including direct epitaxy on Si substrate not only may reduce costs compared to epitaxy on Ge or Si—Ge buffer layer, but also may provide a larger pool of large bandgap semiconductors to choose from. This may be particularly useful when some of the large bandgaps are difficult to achieve by epitaxy of lattice matched semiconductor materials on Ge or Si—Ge buffer layer. Thus, with a combination of different semiconductor materials with different bandgaps (and often different lattice constants), the systems described herein may be employed to absorb most portions of the solar spectrum. In one embodiment, for semiconductor materials with smaller lattice constants, Si substrate (a=5.431 A) may be employed, while for those with bigger lattice constants, an intermediate layer containing Ge (a=5.657 A) may be disposed over the Si first and serve as a virtual substrate. In the case of those semiconductors with intermediate lattice constants a Si—Ge alloy (the lattice constant may be anywhere between 5.431 and 5.657 A) may be employed. One surprising benefit of the systems described herein is that all of these materials may be grown on a common inexpensive Si substrate, be it direct epitaxy on Si, or through a buffer layer of Ge or Si—Ge alloy on the Si substrate which acts as a virtual substrate.

In one embodiment, at least one of the solar cells may comprise a plurality of layers disposed over the silicon-containing substrate. For example, the cell may comprise a first layer comprising silicon. The first layer may be doped or undoped. Depending on the application, the first layer may be doped more heavily than the substrate or doped at the same level as the substrate. In one alternative embodiment, the first layer may be doped more lightly than the substrate. The solar cell may comprise a second layer disposed over the first layer, and the second layer may comprise a semiconductor material, such as germanium. Disposed over the second layer may be additionally a third layer comprising a semiconductor material. Additional layers may be included. For example, multiple layers comprising different layers and/or qualities of Ge (or any other suitable semiconductor material) may be included.

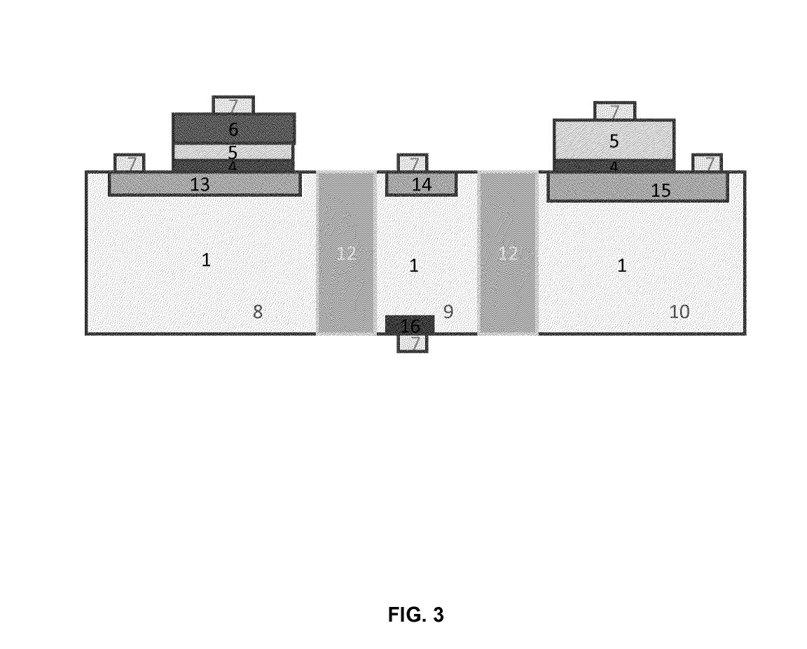

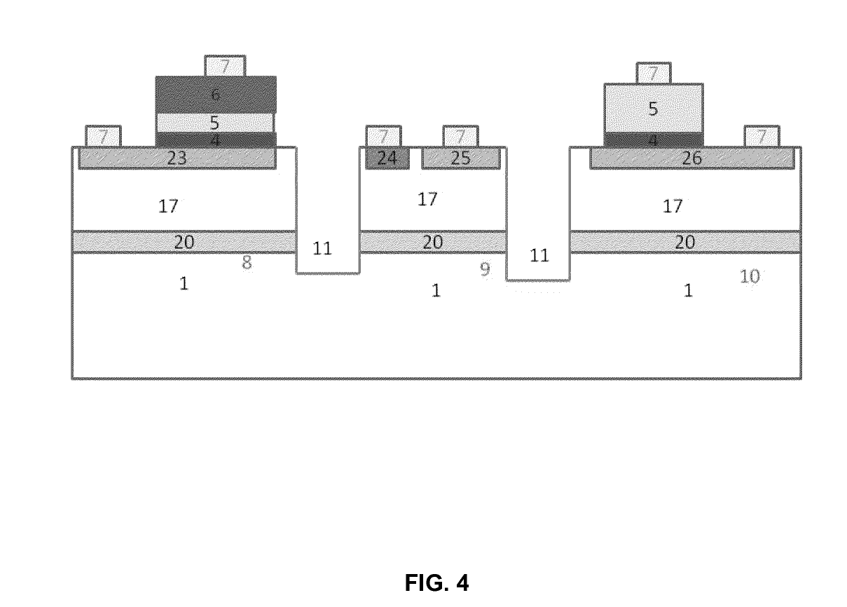

In one embodiment, the Si substrate may be doped by either p- or n-type carriers. Doping may be at a low level (“lightly doped”) or high level (“heavily doped”). As shown in the embodiment illustrated in FIG. 2, heavily doped layers 17, 18, 19, and 21 are disposed over the top surface of the regions 8, 9, 10, and 11, respectively. Layers 17, 18, 19 and 21 may have the same or different doping type relative to the substrate; and in fact, some of them may not need to be heavily doped; they are shown here only for illustration purposes. Details of most of these layers are further illustrated in FIGS. 3 and 4.

As an example, the left regions in this embodiment (17 and 21) may be used for cells made of semiconductor compounds or their alloys, the middle region for a Si cell, and the right for a Ge cell. For the purpose of illustration, the semiconductor material in the cell herein may be a III-V semiconductor material. For a cell comprising semiconductor compound(s) or their alloys which has/have a lattice constant closely matched to that of Ge, a Ge buffer layer 4 is grown on the heavily doped layer 17, and another Ge layer 5 with higher quality may be deposited later. Over layer 5, a semiconductor material, such as AlGaAs, InGaP₂, GaAs, ZnSe, etc., may be epitaxially grown as layer 6, which may contain a p-n junction by adjusting the doping versus thickness. Additionally, if the semiconductor compound(s) or their alloys has/have a lattice constant closely matched to that of Si, it/they may be grown epitaxially on the silicon layer 21 directly as layer 22 without incorporating germanium layers as in region 11. Element 7 denotes metal contacts for the two terminals of each cell. For all of the figures presented herein, the same numeral represents the same element. The middle cell may be a Si cell with all-top or top and bottom contacts. In one embodiment, the Si cell layer 18, preferably may have an opposite doping to the substrate in order to form a p-n junction. In the Ge cell on the right, layers 4 and 5 may be Ge buffer and device layer, respectively.

In one embodiment, the system may comprise silicon-based parallel multijunction solar cells. For example, the system may be a part of a concentrating photovoltaic system adapted to split solar spectrum. Or the system can be integrated with microelectronic or other optoelectronic devices on the same chip and supply power to them.

The Ge-containing epitaxial film, containing Ge and/or Si₁₋ₓGeₓ alloy, may be fabricated by any known method, as described further below. Germanium epitaxy on single crystalline Si substrates may allow high quality devices for optoelectronics and telecommunication to be made on inexpensive (e.g., Si) substrates, enabling integration with microelectronic circuits fabricated through the standard Si CMOS technology. One way to obtain low dislocation density Ge films on Si may be to use a graded buffer layer of Si₁₋ₓGeₓ and vary the Ge composition gradually from 0 to 1. The drawback of this technique may be that the buffer layer has to be quite thick (≧8 μm) and the growth needs to be interrupted for chemical mechanical polishing (“CMP”) to flatten the surface. Another method is to employ a constant composition buffer through a two-step deposition, where a thin Ge buffer layer is deposited on Si at low temperature (<400° C.), followed by a higher temperature (e.g., 500° C.-800° C.) device film deposition and thermal annealing. The dislocation density in the Ge film grown using the two-step deposition may be one order of magnitude higher than that of the Ge film grown using the graded buffer, but the growth may be faster, less expensive, and no CMP is needed. In one embodiment, the two-step method may be better suited for vertical p-i-n junction diodes and photovoltaic devices because the thick graded buffer layer has high dislocation density, which could reduce carrier collection efficiency and increase leakage. In another embodiment, the two-step deposition method may be preferred because it may be faster and less expensive, and in some cases having minimal need of CMP, in comparison to the graded buffer. The Si₁₋ₓGeₓ alloy may be grown similarly. Depending on the application and the need thereof, either of the aforementioned methods, along with other suitable epitaxy methods, may be employed as the methods described herein.

In one embodiment, an epitaxial Ge-containing film (e.g., Ge, Si₁₋ₓGeₓ, etc.) disposed over a Si layer or Si substrate may also be employed as a virtual substrate for a semiconductor film epitaxy, particularly when the lattice constant of the semiconductor material is comparable to that of Ge or Si₁₋ₓGeₓ. In one embodiment, the semiconductor material may be a III-V and/or II-VI material. For example, GaAs has a lattice constant comparable to that of Ge. This may open the door to integrating a III-V or II-VI semiconductor material and Ge optoelectronic devices with Si photovoltaic cells/detectors and CMOS electrical circuits. In one embodiment, a II-VI semiconductor material may have bigger bandgap (e.g., 2.82 eV) than any III-V material that is lattice-matched to Ge, and thus may be beneficial for achieving higher parallel multijunction system efficiency if included. In one embodiment, for III-V semiconductor materials with lattice constants larger than that of Ge, an epitaxial growth process similar to that of Ge on Si may be employed.

In one embodiment described herein, the solar cell may include at least one of (i) a first semiconductor layer disposed over the substrate, the first layer comprising at least one semiconductor material comprising at least one of a compound and an alloy; and (ii) a first Ge-containing layer disposed over the substrate, the first layer comprising a Ge-containing material, and a second layer disposed over the first layer, the second layer comprising at least one semiconductor material. In one embodiment, the solar cell may comprise (i) when a lattice constant of the semiconductor material is comparable to a lattice constant of the silicon. In another embodiment, the solar cell may comprise (ii) when a lattice constant of the semiconductor material is comparable to a lattice constant of the Ge-containing material.

The solar cells described herein may comprise at least one epitaxial layer comprising a semiconductor layer. One important condition for epitaxy is lattice matching between the layer being epitaxially grown and the substrate upon which the layer is grown. In one embodiment, a semiconductor material may be directly grown on the silicon substrate if its lattice constant is comparable to that of Si (lattice constant a=5.431 A). One example is GaN_{0.029}P_{0.971}, which has a bandgap energy more than 2.26 eV. Comparable lattice constants may refer to two lattice constants differing from each other by less than about 100% —e.g., less than about 80%, 60%, 50%, 25%, 20%, 15%, 10%, 5%, 2%, 1%, 0.5%, 0.1%, 0.05%, 0.01%, 0.005%, 0.001%, or less.

The solar cells may have different material properties or geometries (e.g., different size and/or shape from one another). Each cell may absorb a certain range of wavelength of the incident light (e.g., solar energy) best suited for its bandgap. Thus, the cell may be adjusted with respect to the material, size, shape, etc., depending on the applications. In one embodiment, different solar cells are employed for absorption of photons of different wavelengths. For example, because the bandgap wavelengths of GaAs, Si, and Ge are 0.87 μm, 1.1 μm, and 1.85 μm, respectively, the GaAs cell may be employed for the absorption of photons with wavelengths less than 840 nm, while Si may absorb photons up to 1 μm, and Ge may absorb even longer wavelengths. As another example, bandgap wavelengths of Ge-lattice matched ZnS_{0.035}Se_{0.965} and In_{0.51}Ga_{0.49}P are 0.45 and 0.66 μm. The ZnS_{0.035}Se_{0.965} cell may be employed for the absorption of photons with wavelengths less than 450 nm, while the In_{0.51}Ga_{0.49}P cell may absorb photons up to 650 nm. The specific wavelength division may be optimized based on each cell with respect to factors such as thickness and quality.

### Method of Making

Provided in one embodiment is an integrated approach to fabricate an integrated solar cell system. For example, in one embodiment, a common Si substrate may be used, and laterally aligned III-V, Si and Ge cells may be used to receive different spectral bands optimized for highest efficiency. Alternatively, the solar cells may not need to be laterally aligned if different concentration/spectrum splitting configurations are used. In one embodiment, instead of using an expensive Ge substrate, the method described herein surprisingly allows a single crystalline thin film containing Ge to be grown on top of an inexpensive Si substrate through epitaxial growth. The Ge-containing film is much thinner than a wafer substrate, and it may be subsequently used as a virtual substrate for cells containing semiconductor materials, thereby reducing the need for expensive but commonly used substrates (e.g., GaAs or InP).

The architecture of an integrated solar cell described herein may allow easy mounting of the cells with respect to the spectrum splitter/concentrator, and using the Si substrate may reduce cost. Furthermore, the distance between individual cells may be small relative to mounting pre-existing stand-alone solar cells. For example, the distance may be less than 1 mm—e.g., less than 0.5 mm, 0.1 mm, 0.05 mm, 0.01 mm, or smaller. In one embodiment, the distance is in the range of a few tens of microns. For example, in one embodiment, the distance may be limited by optical lithography and the chosen electrical isolation technique. As a result, the presently described articles/systems may reduce optical loss, as compared to physically mounting individual cells on a common substrate, which may necessitate a distance of millimeters between adjacent cells.

Provided in one embodiment is a method of making an article or system, the method comprising: disposing a plurality of solar cells over a substrate comprising silicon; and isolating electrically at least some of the plurality of solar cells. The solar cells and the substrates may be any of those aforedescribed. In one embodiment, the method may further include a method of making at least one of the solar cells. For example, the method of making may include disposing a germanium layer over a silicon substrate (wafer); and disposing additional layers comprising one or more semiconductor materials over the germanium layer.

### Electrical Isolation

In one embodiment, because all the cells share the same conductive substrate, the cells may be electrically isolated so that they do not crosstalk and degrade the performance of one another. As aforedescribed, any suitable techniques of electrical isolation may be used. The electrical isolation may be accomplished by various techniques. For example, the isolation may be accomplished with at least one of thermal gradient zone melting, trench etching, and vertical junction isolation. In another embodiment, the isolation may include doping at least substantially an entire thickness of a region of the substrate.

In one embodiment, the technique of silicon-on-insulator (“SOI”) substrate may be employed. For example, the cells are disposed over different regions of the device layer on the substrate, and the regions between the cells may be etched away. As a result, in one embodiment, the cells may be isolated horizontally by the etched trench and/or vertically by a buried oxide layer (now partially exposed). Moreover, in the case of a thick device layer, a deep Si etch may be employed for cell isolation. An alternative technique may be to etch the substrate to create a trench between the cells and additionally (and optionally) refill the trenches with an insulating and/or a dielectric material, such as oxide and/or nitride—e.g., silicon dioxide or silicon nitride.

In another embodiment, junction isolation may be employed to isolate electrically the cells, wherein the p-n-p or n-p-n regions in Si may be fabricated (as diodes) and connected in series. In one embodiment, one of the diodes may be reverse-biased at all times, and no current will flow below the breakdown voltage except for the leakage current. This method may generally be suitable for microelectronics and the benefit thereof may include achieving electrical isolation between different regions of Si while maintaining the substrate's mechanical integrity.

One of the techniques employed in the methods described herein may be a gradient-driven migration method, such as electromigration. In one embodiment, the methods described herein may involve thermal migration—e.g., a technique called thermal gradient zone melting (“TGZM”). In another embodiment, TGZM may involve at least one of sputtering, electron beam evaporation, photolithography, screen printing, ink jet printing, and cold-spray deposition. TGZM may be employed to dope silicon throughout a substrate thickness as large as several hundred microns. (See e.g., W. Pfann, Zone Melting, Huntington, N.Y.: Krieger, 1978). In one embodiment, in order to achieve sufficient isolation, Si may be doped through the entire (or substantially entire) thickness of a silicon substrate (e.g., wafer)—in some cases this thickness may be several hundreds of microns. Alternatively, Si may be doped through only a portion of the thickness. Note that traditional doping methods (i.e., diffusion or ion implantation) will not be adequate to penetrate so deeply into Si.

In one embodiment, after a dopant material is deposited over the substrate surface, the dopant material may be employed to create different doping type(s) in the Si substrate (e.g., wafer) compared to the existing substrate doping. The deposition may be carried out via sputtering, electron beam evaporation, and the like, and patterned photolithographically. Alternatively, an array of droplets containing (or is) the dopant material may be deposited simultaneously by screen printing, ink jet printing, cold-spray deposition, etc. onto the substrate.

TGZM may be employed to accomplish isolation in one embodiment. For example, the other (non-deposited) side of the substrate may be heated to a high temperature above the eutectic temperature of the dopant material and Si. In one embodiment, the dopant may subsequently melt, dissolve part of the substrate material, and the molten zone may migrate along the vertical thermal gradient created by the one-sided heating. As the zone travels, more substrate material may be dissolved on the hotter side, and the cooler side re-solidifies epitaxially. As a result, the doping level may be determined by the solid solubility of the dopant in the substrate material. Any suitable dopant may be used. For example, aluminum may be used as a p-type dopant, and n-p-n junctions may be created through n-type silicon substrates. TGZM may be employed to isolate electrically multiple areas of a monolithic integrated solar cell array having series-connected identical unit cells in order to achieve high voltage output. The TGZM process may also be employed to create alternating p-n regions with interdigitated top contacts in photovoltaic cells to improve carrier collection. The approach employed in one embodiment described herein differs from the pre-existing methods at least in that the purpose of the method is to isolate individual photovoltaic cells that differ from one another and will not be connected in series.

FIG. 3 illustrates an embodiment in which the Si substrate 1 is divided into three electrically isolated regions 8, 9, and 10 by two vertically doped regions 12 created using the TGZM method. The substrate may be lightly doped (e.g., n-doped)—the dopant used for TGZM may be, for example, aluminum. N-type doping of a lightly p-doped substrate with appropriate material is also possible. Regions 13 and 15 may be heavily doped in either p-type or n-type for electrical contacts in the III-V (or the semiconductor such as II-VI, I-III-VI₂ or II-IV-V₂) and Ge cells, and region 14 may be oppositely doped to the substrate in order to form a p-n junction in the Si cell. Region 16 may be heavily doped with the same dopant type as the substrate for contact. This region and its associated contact 7 may be located on the back surface of the substrate, or the front surface adjacent to region 14.

Another embodiment for electrical isolation between the integrated solar cells is shown in FIG. 4, wherein trench (mesa) and junction isolation are used in combination. In one alternative embodiment, trench and junction isolation are not used in combination. Region 11 is a trench that may be created by wet or dry etching Si in regions 17, 20, and 1.

An insulating material, such as silicon dioxide or silicon nitride, may be additionally disposed over at least a portion of the trench, thereby, for example, passivating the portion. The exposed portion of the trench may be further passivated. In one embodiment, to passivate the exposed sidewalls of the trench, a thermal oxide may be grown conformally or an oxide layer may be deposited into the trench. As shown in the embodiment illustrated in FIG. 4, inside each cell there may be a heavily doped layer 20 with opposite conductivity type to the substrate. The depth of the trench may extend passing layer 20. Region 17 over the passing layer 20 in this embodiment has the same doping type as the substrate in this embodiment. Consequently, lateral isolation may be achieved by the trenches, and each cell may be isolated from the substrate by the vertical back to back junctions formed between regions 17, 20, and 1. In one embodiment, regions 23, 24, 26 may be heavily doped for ohmic contacts, and region 25 may contain the opposite doping type to the substrate to form a p-n junction in the Si cell. The embodiment as shown in FIG. 4 differs from FIG. 3 in at least that both electrodes of the Si cell are located on the top surface of the wafer. To fabricate the vertical junctions for isolation, layer 20 may be, for example, diffused or ion implanted into the substrate, and further followed by epitaxy of layer 17. Alternatively, epitaxial wafers with n-p⁺-n or p-n⁺-p (corresponding to regions 17, 20, and 1) doping profile may be used as the starting material.

In some cases, the junction isolation may become ineffective when exposed to light. The methods and systems described herein may overcome this challenge and avoid the difficulty of the junction isolation being ineffective when exposed to light. For example, the heavily doped regions 12 in FIG. 3 and regions 20 in FIG. 4 may have a width/thickness of at least two minority carrier diffusion lengths and a minority carrier life time of no more than 10 nanoseconds—e.g., 5 nanoseconds, 2 nanoseconds, or less. Depending on the application, the width/thickness may be at least 3, 4, 5, or more, minority carrier diffusion lengths. In one alternative embodiment, so as to simplify fabrication, two or more individual cells may share one common electrode, thus not needing electrical isolation.

One benefit of the systems/articles described herein is that the distance between individual cells for integrated solar cells may surprisingly be much smaller than what may be achieved by physically mounting individual cells on a common substrate, thereby reducing optical loss related to spectrum splitting. Additionally, the presently described systems may achieve high optical-electrical energy conversion efficiency and low cost. In one embodiment, epitaxial Ge-on-Si may be used as a virtual substrate for semiconductor material epitaxy (e.g., III-V, and/or II-VI material, and/or I-III-VI₂ and/or II-IV-V₂) to absorb selected parts of the solar spectrum. Also, one advantage of spectrum splitting provided in the embodiments herein is that a bandgap appropriate cell may be employed for each spectral range, and when a higher bandgap cell becomes weakly absorbing, another cell with a smaller bandgap will take over and boost the absorption. Through this “relaying” action, absorption may be kept high within the whole solar spectrum. Furthermore, there is no need for current matching, therefore each absorbed photon counts, thereby leading to high overall efficiency.

### NON-LIMITING WORKING EXAMPLES

### Example I

### Estimation of System Efficiency and Optimization of Spectrum Splitting

Simulations studies were conducted to investigate the system efficiency and optimization of spectrum splitting. Epitaxial Ge film on an Si substrate may be used to fabricate a Ge solar cell, and more importantly, it may be subsequently used as a virtual substrate for III-V, II-VI, I-III-VI₂, and II-IV-V₂ semiconductor film epitaxy, if they have comparable lattice constants to that of Ge, for example, In_{0.51}Ga_{0.49}P: 5.656 A; and GaAs: 5.653 A (Ge: 5.657 A). In order to estimate the efficiency of multiple parallel junction solar cells and optimize spectrum splitting, studied herein via computer simulation were various combinations of four types of solar cells, commonly used in concentrating photovoltaic (CPV) systems, that may be easily integrated on an Si substrate: In_{0.51}Ga_{0.49}P (InGaP), GaAs, Ge and Si

Assumptions:

For simplicity and in order to estimate the efficiency limit, the following assumptions were made:

(1) realistic and simple design of individual cells: planar AR coating, no light trapping structures;

(2) appropriate absorber thicknesses determined from individual cell efficiency simulation and minimization of processing complexity: InGaP: 2 μm; GaAs: 2 μm; Si: 675 μm (thickness of a typical 6 inch diameter wafer); Ge: 2.5 μm;

(3) fill factor equals 0.86 (for ideal diodes);

(4) no shadowing;

(5) 100% carrier collection; and

(6) no optical loss from the beam concentrator/splitter.

Methodology:

The absorption spectrum of an individual solar cell A(λ) was calculated using a commercial Finite Difference Time Domain (FDTD) simulation software package, and the short circuit current density J_{sc} was then acquired from

$${J}_{sc} = q {\int }_{{λ}_{1}}^{{λ}_{2}} A ( λ ) s ( λ ) d λ ,$$

where q is electronic charge, s(λ) was incident solar photon flux density from the AM1.5 spectrum, and [λ₁, λ₂] was the spectral range assigned to a certain solar cell. The open circuit voltage V_{oc} was obtained from

$${V}_{oc} = \frac{kT}{q} ln ( \frac{{J}_{sc}}{{J}_{s 0}} + 1 ) ,$$

where k is the Boltzmann's constant, T=300 K, and Jₛ₀ is the diode reverse bias saturation current taken from experimental values. Individual cell efficiency was then calculated from

$$η = \frac{{J}_{sc} {V}_{oc} FF}{{P}_{in}} ,$$

where FF was the fill factor, and Pᵢₙ the incident solar power per unit area under AM 1.5 conditions.

Solar cell efficiency under X times concentration was calculated by multiplying the efficiency under one sun by the factor

$$1 + \frac{kT}{q {V}_{oc}} ln X .$$

System efficiency of the parallel multijunction cell was the sum of that of individual cells. Matlab simulation was performed to determine the optimal cell combination and spectrum splitting wavelengths to achieve the highest overall system efficiency.

Results:

It was found that for a specific parallel junction cell, the optimal spectrum splitting points did not significantly change with the concentration level, and they were always near the band edge of each individual cell—e.g., for the four parallel junction (“PJ”) InGaP—GaAs—Si—Ge cell, splitting the solar spectrum at λ₁=660 nm, λ₂=840 nm, and λ₃=1110 nm renders the highest efficiency, η=33.8% under one sun, and 38.9% under 200× concentration (assuming 200 suns).

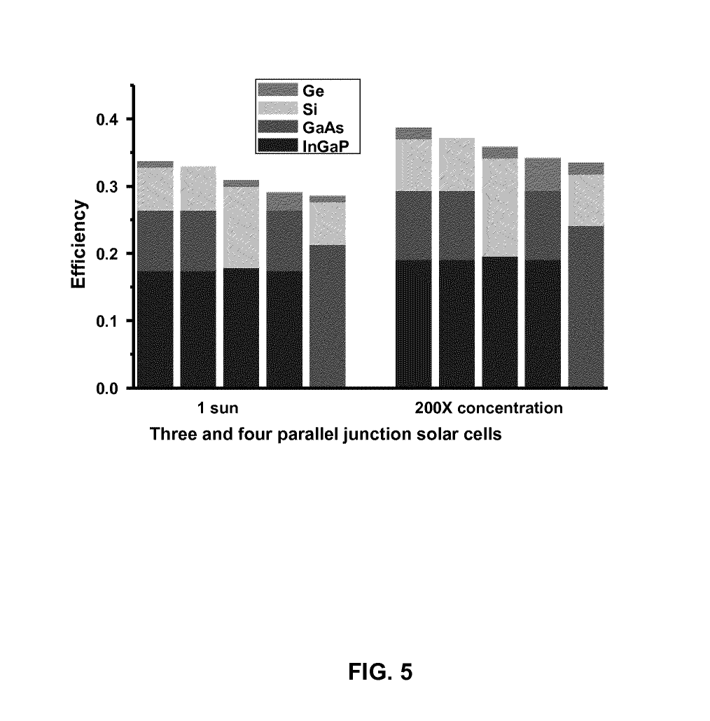

FIG. 5 shows the cell efficiency for various combinations of 3PJ and the 4PJ cells. The 4PJ cell has the highest η at 33.8% under one sun, and 38.9% under 200× (assuming 200 suns). Among all of the 3PJ cells, InGaP—GaAs—Si cell was found to have the highest efficiency, and GaAs—Si—Ge cell the lowest.

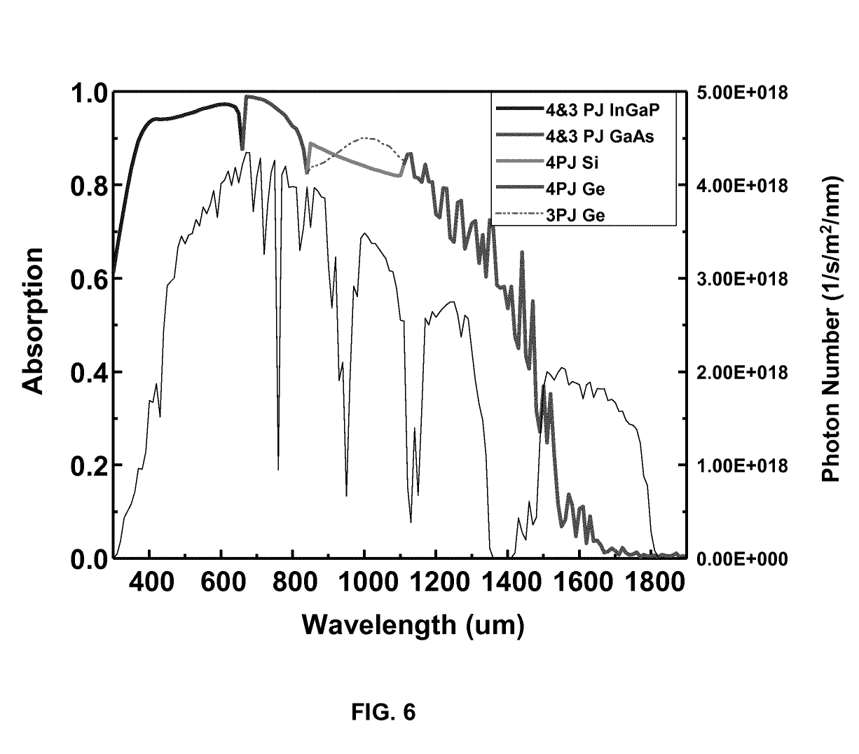

FIG. 6 shows that the absorption by the parallel junction cells described herein is very high across the whole solar spectrum—i.e., it is only limited by the front side reflection for the Si cell and the absorber thickness for the Ge cell. Not to be bound by any theory, but this high efficiency is due to the optimal utilization of the solar spectrum.

Including high bandgap cells is beneficial for achieving high system efficiency. One difference between the two absorption spectra in FIG. 6 is in the range of about 840 to about 1110 nm, where the 3PJ cell absorbs more photons in most of this band with high solar photon flux. Therefore, not to be bound by any theory, but the higher efficiency of the 4PJ cell may be due to the higher V_{oc} of Si originating from its bigger bandgap. Hence, it may be inferred that including higher bandgap cells than InGaP, which are lattice-matched to Ge, would render higher overall efficiency than the 4PJ cell discussed herein.

System efficiency may be further enhanced by additional improvement of the design of each individual solar cell for the wavelength range assigned to it after initial spectrum splitting optimization, such as AR coating optimization and inclusion of light trapping structures, etc. For instance, simply changing the Si₃N₄AR coating thickness from 70 nm to 110 nm for the Si cell in the 4PJ can increase overall efficiency to 33.8% and 38.9% under 1 and 200 suns, respectively.

### Example II

### Isolation Trench Depth and Width Simulation

To gain experience in integrated solar cell fabrication for spectrum splitting application, parallel junction Si and Ge cells were fabricated on a common Si substrate. For electric isolation between the adjacent Si and Ge solar cells, isolation trenches were used as shown in FIG. 4. To simplify processing, there was no heavily doped layer 20.

Intuitively, the wider and deeper the isolation trench, the lower the crosstalk between adjacent solar cells. However, a wider trench may entail more optical loss due to the possibly continuous nature of the split spectrum, and deep trenches give rise to fabrication challenges: during photolithography, the surface tension of the photoresist will be broken and it will be difficult to coat the area adjacent to the trenches. Therefore, narrow trenches were preferred to reduce optical loss, and shallow trenches are favored for processing feasibility.

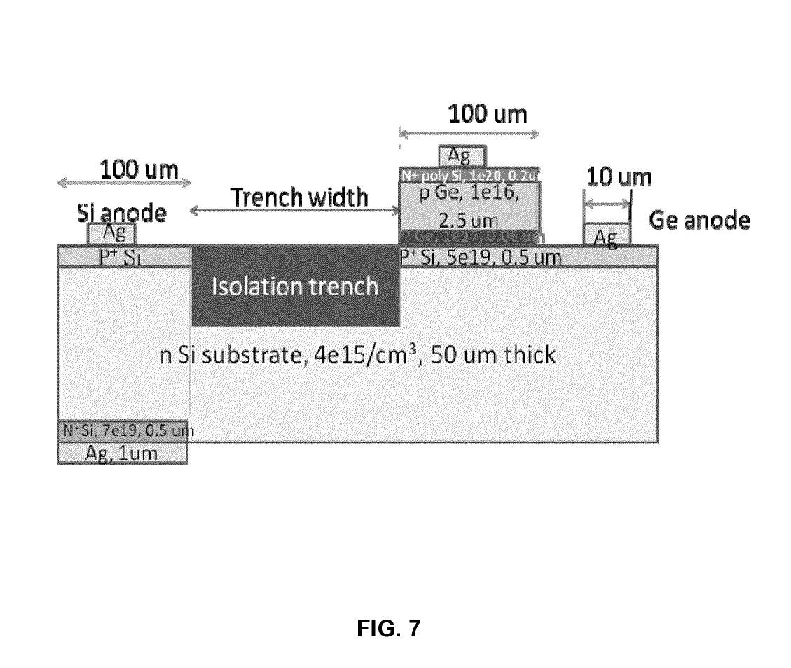

To obtain reasonable trench width and depth, electrical simulation was performed using software Silvaco, especially its device simulator Atlas. The simulated device is shown in FIG. 7. A 50 μm substrate thickness was assumed due to the simulation domain size constraint. The isolation trench is filled with SiO₂. The induced current in one cell is monitored when the other cell is biased at a voltage close to its open circuit voltage. For example, the current induced in the Si cell is measured when the Ge cell is biased at 0.4 V, and the current induced in the Ge cell is measured when the Si cell is biased at 0.7 V.

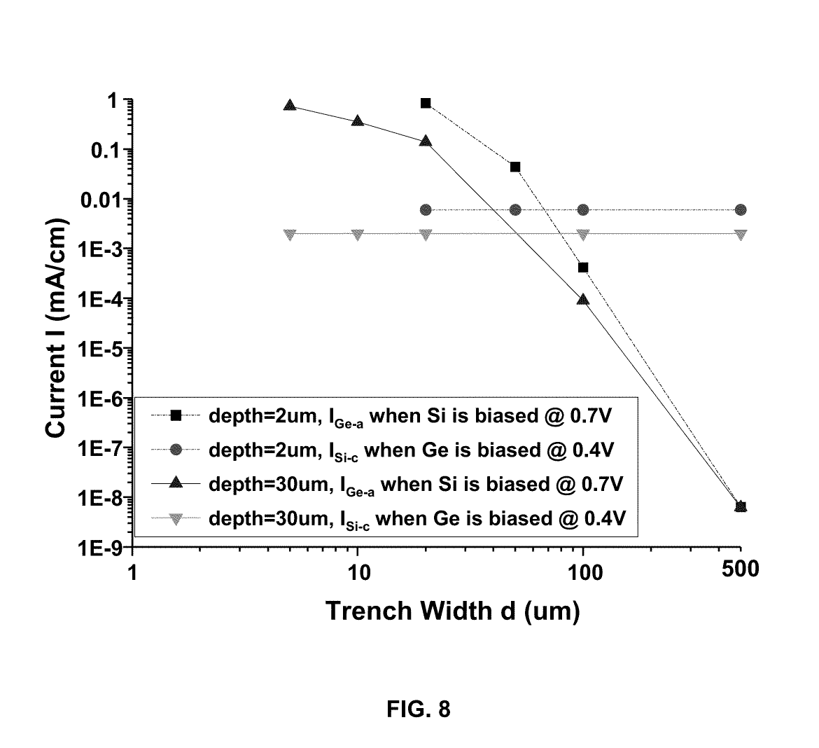

FIG. 8 illustrates the crosstalk current vs. the width of the isolation trench for two different trench depths: 2 and 30 μm. FIG. 8 indicates the following: first, a deeper trench reduces crosstalk. Compared to a 2 μm deep trench, a trench 30 μm deep induces smaller current in both the Ge and Si cells when the other is biased. For instance, when the trench width is 100 μm and the Ge cell is biased at 0.4V, a 2 μm deep trench causes 0.006 mA/cm (this unit assumes a solar cell width of 1 cm) current in Si cell, while a 30 μm deep trench entails a current I=0.002 mA/cm in Si cell. Second, when the Ge cell is biased, the induced current in Si cell does not vary with trench width. Not to be bound by any theory, but this may be attributed to the fact that the Ge cell is only biased down to the top heavily doped layer in the Si substrate, and if a trench cuts into that layer, the lateral component of the electric field will be terminated, no matter how wide the trench is. Third, when the Si cell is biased, the induced current in Ge cell does not vary much with trench depth, but changes rapidly with trench width. Not to be bound by any theory, but this may be attributed to the fact that the Si cell is already biased from top to bottom of the substrate, such that the trench depth does not matter much; however, as the trench width increases, the electric fields decrease.

Thus, based on the results of this study (which was conducted assuming an absence of light), it was concluded that it would be desirable to have a trench width of at least 50 μm and a trench depth no shallower than 2 μm, although wider trenches entail more optical loss. A 50 μm wide and 2 μm deep trench causes I=0.04 mA/cm in Ge cell when Si cell is biased, and I=0.006 mA/cm in Si cell when Ge cell is biased. For comparison, the current generated from light absorption of 100× concentrated sunlight in each cell (100 micron×1 cm) is approximately the equivalent of 20 mA/cm per cell, a value that increases with concentration.

### CONCLUSION

All literature and similar material cited in this application, including, but not limited to, patents, patent applications, articles, books, treatises, and web pages, regardless of the format of such literature and similar materials, are expressly incorporated by reference in their entirety. In the event that one or more of the incorporated literature and similar materials differs from or contradicts this application, including but not limited to defined terms, term usage, described techniques, or the like, this application controls.

While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments of the invention may be implemented in any of numerous ways. For example, some embodiments may be implemented using hardware, software or a combination thereof. When any aspect of an embodiment is implemented at least in part in software, the software code may be executed on any suitable processor or collection of processors, whether provided in a single computer or distributed among multiple computers.

Also, the technology described herein may be embodied as a method, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.” Any ranges cited herein are inclusive.

The terms “substantially” and “about” used throughout this Specification are used to describe and account for small fluctuations. For example, they may refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” may refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

The claims should not be read as limited to the described order or elements unless stated to that effect. It should be understood that various changes in form and detail may be made by one of ordinary skill in the art without departing from the spirit and scope of the appended claims. All embodiments that come within the spirit and scope of the following claims and equivalents thereto are claimed.

What is claimed:

1. An article, comprising:
a substrate comprising silicon; and
a plurality of solar cells disposed over the substrate, wherein at least one of the plurality of the solar cells comprises one of:
(i) a first semiconductor layer disposed over the substrate, the first layer comprising at least one semiconductor material; and
(ii) a first Ge-containing layer disposed over the substrate, the first layer comprising a Ge-containing material, and a second layer disposed over the first layer, the second layer comprising at least one semiconductor material.

2. The article of claim 1, wherein the solar cells comprise a plurality of semiconductor materials having multiple bandgap values.

3. The article of claim 1, wherein the at least one of the plurality of the solar cells comprises (i) when a lattice constant of the semiconductor material is comparable to a lattice constant of the silicon.

4. The article of claim 1, wherein the at least one of the plurality of the solar cells comprises (ii) when a lattice constant of the semiconductor material is comparable to a lattice constant of the Ge-containing material.

5. The article of claim 1, wherein the Ge-containing material comprises at least one of germanium and a silicon-germanium alloy.

6. The article of claim 1, wherein the first Ge-containing layer comprises a single crystalline germanium film.

7. The article of claim 1, wherein the semiconductor material comprises at least one of a III-V semiconductor, a II-VI semiconductor, a I-III-VI₂ semiconductor, and a II-IV-V₂ semiconductor.

8. The article of claim 1, wherein the semiconductor material comprises at least one III-V semiconductor material selected from AlₓGa_{y}In_{1-x-y}P, AlₓGa_{y}In_{1-x-y}As, and AlₓGa₁₋ₓN_{y}P_{1-y}, where 0≦x≦1 and 0≦y≦1.

9. The article of claim 1, wherein the semiconductor material comprises at least one II-VI semiconductor material comprising ZnₓCd₁₋ₓS_{y}Se_{z}Te_{1-y-z}, where 0≦x≦1, 0≦y≦1 and 0≦z≦1.

10. The article of claim 1, wherein the semiconductor material comprises at least one I-III-VI₂ semiconductor material comprising Cu(AlₓGa_{y}In_{1-y})(S_{z}Se_{1-z})₂, where 0≦x≦1, 0≦y≦1, and 0≦z≦1.

11. The article of claim 1, wherein the semiconductor material comprises at least one II-IV-V₂ semiconductor material comprising Zn(SiₓGe₁₋ₓ)P₂, where 0≦x≦1.

12. The article of claim 1, wherein the semiconductor material comprises at least one of a homogeneous p-n junction and a heterogeneous p-n junction.

13. The article of claim 1, wherein the semiconductor material comprises at least one of an element, an alloy, and a compound semiconductor material.

14. A concentrating photovoltaic system adapted to split solar spectrum, the system comprising the article of claim 1.

15. An article, comprising:
a substrate comprising silicon; and
a plurality of solar cells disposed over the substrate and electrically isolated from one another;
wherein at least some of the solar cells comprise semiconductor materials having different bandgap values.

16. The article of claim 15, wherein at least one of the plurality of the solar cells comprises one of:
(i) a first semiconductor layer disposed over the substrate, the first layer comprising at least one semiconductor material selected from a III-V, II-VI, I-III-VI₂, and II-IV-V₂ material; and
(ii) a first Ge-containing layer disposed over the substrate, the first layer comprising at least one of germanium and a silicon-germanium alloy, and a second layer disposed over the first layer, the second layer comprising at least one semiconductor material selected from a III-V, a II-VI, a I-III-VI₂, and a II-IV-V₂ material.

17. The article of claim 15, wherein at least some of the solar cells are electrically isolated from one another by at least one of silicon-on-insulator wafers, trench, and vertical junction isolation.

18. The article of claim 15, wherein at least some of the solar cells are electrically isolated from one another by at least one layer comprising a silicon doped by a different type than the substrate.

19. The article of claim 15, wherein at least some of the solar cells are electrically isolated from one another by at least one of a trench and an insulating material comprising at least one of an oxide and a nitride.

20. The article of claim 15, wherein the Ge-containing layer comprises an epitaxial film.

21. A method, comprising:
disposing a plurality of solar cells over a substrate comprising silicon; and
isolating electrically at least some of the plurality of solar cells,
wherein at least some of the solar cells comprise semiconductor materials having different bandgap values.

22. The method of claim 21, further comprising a method of making at least one of the solar cells, the method comprising one of:
(i) disposing a first semiconductor layer over the substrate; the first layer comprising at least one semiconductor material comprising at least one of a compound and an alloy; and
(ii) disposing a first Ge-containing layer over the substrate, the first layer comprising a Ge-containing material, and a second layer disposed over the first layer, the second layer comprising at least one semiconductor material.

23. The method of claim 21, wherein electrically isolating further comprises at least one of thermal gradient zone melting, trench etching, and vertical junction isolation.

24. The method of claim 21, wherein electrically isolating further comprises doping at least substantially an entire thickness of substrate.

25. The method of claim 21, wherein further comprising disposing a semiconductor layer over a substrate, the semiconductor layer comprising an epitaxial film.
